(19) United States
(12) Patent Application Publication
(10) Pub. No.: US 2015/0340527 A1
(43) Pub. Date: Nov. 26, 2015

(54) SOLAR CELL MODULE

(71) Applicant: KYOCERA CORPORATION, Kyoto (JP)

(72) Inventors: Kazushi MOTONAGA, lse-shi, Mie (JP); Sou TAKAMURA, lse-shi, Mie (JP); Koichi YANAGIDA, lse-shi, Mie (JP); Takafumi MIYAKE, lse-shi, Mie (JP)

(21) Appl. No.: 14/758,497

(22) PCT Filed: Dec. 19, 2013
(86) PCT No.: PCT/JP2013/084139

§ 371 Date: Jun. 29, 2015

(30) Foreign Application Priority Data
Dec. 27, 2012 (JP) 2012-285573

(51) Int. Cl. H01L 31/044; H02S 40/36; H01L 31/049

(52) U.S. Cl. CPC H01L 31/044; H01L 31/049; H02S 40/36

(57) ABSTRACT

A solar cell module according to one embodiment of the present invention includes a first device group and a second device group each including a plurality of solar cell devices electrically connecting to each other, and a bypass device that is electrically connected to the first device group and the second device group. Further, in the embodiment, a covering member that covers the first device group, the second device group, and the bypass device, and a protective sheet that is located on the covering member, are included. In the embodiment, the protective sheet includes an opening portion that is located at a position facing the bypass device.

### TECHNICAL FIELD

The present invention relates to a solar cell module.

### BACKGROUND ART

In a solar cell module, if dust or the like is piled up on a light-receiving face side of a solar cell device, a power generation amount of the solar cell device is lowered. At this time, resistance within the solar cell device may increase, and heat may be generated. Therefore, in the solar cell module, a bypass device is arranged within a terminal box in order to bypass a current flowing through the solar cell device where the resistance has increased. The terminal box is arranged on a protective sheet which is placed on a rear face of the solar cell module. In Japanese Unexamined Patent Application Publication No. 5-291602, a solar cell module in which a bypass device is placed within a covering member which is positioned between a protective sheet and a light-transmitting substrate, is disclosed.

### CITATION LIST

### Problem to be Solved by the Invention

In the solar cell module of Japanese Unexamined Patent Application Publication No. 5-291602, a region of the protective sheet covering a portion which seals the bypass device, protrudes. At this time, in a case of using a covering member of which a thickness is small, a large convex portion is likely to be generated in the protective sheet at the portion where the bypass device is sealed. Due to the convex portion, wrinkles may be radially generated in the protective sheet. Since strength of the protective sheet at the convex portion and the portion where the wrinkles are generated is reduced in comparison with other portions, the portions are likely to be broken. Further, if the wrinkles extend up to an outer peripheral end portion of the protective sheet, water enters a gap between the protective sheet and the covering member due to the wrinkles, from outside. Accordingly, reliability of the solar cell module may be lowered.

One object of the present invention is to provide a solar cell module of which reliability is enhanced.

### Means for Solving the Problems

An embodiment of the present invention provides a solar cell module including a first solar cell device group and a second solar cell device group each including a plurality of solar cell devices electrically connected to each other, and a bypass device that is electrically connected to the first solar cell device group and the second solar cell device group. According to the embodiment, the solar cell module includes a covering member that covers the first solar cell device group, the second solar cell device group, and the bypass device, and a protective sheet that is located on the covering member. In the embodiment, the protective sheet has an opening portion that is located at a position facing the bypass device.

### Advantageous Effects of Invention

According to the embodiment of the present invention, since the opening portion is provided in the protective sheet at a position facing the bypass device, wrinkles are unlikely to be generated in the protective sheet. As a result, the reliability of the solar cell module is enhanced.

### BRIEF DESCRIPTION OF DRAWINGS

FIGS. 1A to 1C are diagrams illustrating a solar cell module according to an embodiment of the present invention, in which FIG. 1A is a plan view when seen from a light-receiving face side, FIG. 1B is a plan view when seen from a rear face side, and FIG. 1C is a cross-sectional view when seen at an A-A′ cross section of FIG. 1A.

FIGS. 2A and 2B are diagrams illustrating an example of a bypass device which is used in the solar cell module according to the embodiment of the present invention, in which FIG. 2A is an exploded perspective view of the bypass device and FIG. 2B is a perspective view illustrating a state after assembling.

FIGS. 3A to 3C are diagrams illustrating the solar cell module according to the embodiment of the present invention, in which FIG. 3A is a plan view illustrating one solar cell device group pulled out from the solar cell module, FIG. 3B is a plan view illustrating a state of a first device group and a second device group being connected by connection wiring and the bypass device, and FIG. 3C is an electrical circuit diagram illustrating the state of the first device group and the second device group being connected.

FIGS. 4A and 4B are diagrams illustrating the solar cell module according to the embodiment of the present invention, in which FIG. 4A is an exploded perspective view illustrating a portion B in FIG. 1B in an enlarged manner and FIG. 4B is a cross-sectional view when seen at a C-C′ cross section of FIG. 1B.

FIG. 5 is a perspective view illustrating another example of the bypass device which is used in the solar cell module according to the embodiment of the present invention.

FIG. 6 is a perspective view illustrating still another example of the bypass device which is used in the solar cell module according to the embodiment of the present invention.

FIGS. 7A and 7B are diagrams illustrating a solar cell module according to another embodiment of the present invention, in which FIG. 7A is a plan view corresponding to FIG. 1B and FIG. 7B is a cross-sectional view when seen at a D-D′ cross section of FIG. 7A.

FIGS. 8A and 7B are diagrams illustrating a solar cell module according to still another embodiment of the present invention, in which FIG. 8A is a plan view corresponding to FIG. 1A and FIG. 8B is a plan view corresponding to FIG. 1B.

FIG. 9 is an electrical circuit diagram of a solar cell module according to still another embodiment of the present invention.

FIGS. 10A and 10B are cross-sectionals view of solar cell modules according to still another embodiment of the present invention.

### MODE FOR CARRYING OUT OF THE INVENTION

A solar cell module according to an embodiment of the present invention will be described with reference to accompanying drawings.

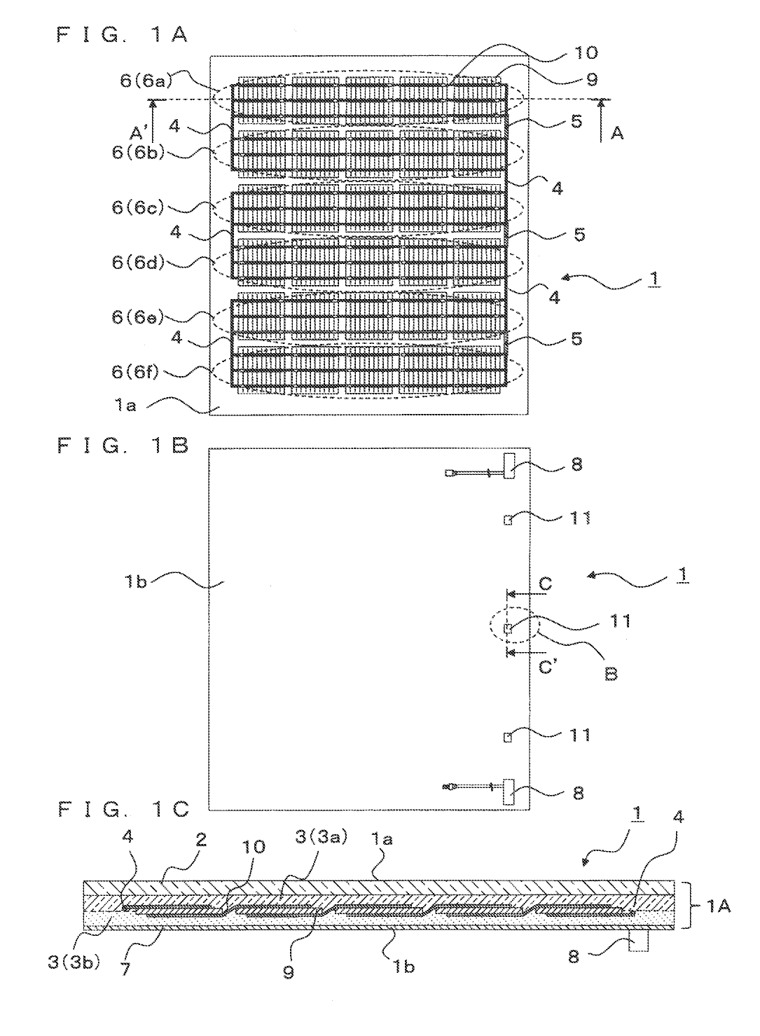

A solar cell module 1 according to an embodiment of the present invention includes a light-receiving face 1a (corresponding to one main face of a light-transmitting substrate 2) that mainly receives light, and a rear face 1b (corresponding to one main face of a protective sheet 7) that corresponds to a rear face of the light-receiving face 1a, as shown in FIG. 1A to 1C. The solar cell module 1 includes the light-transmitting substrate 2, a covering member 3, six solar cell device groups 6 (hereinafter, referred to as device groups 6) which are connected to each other by connection wiring 4 and a bypass device 5, the protective sheet 7 that protects the rear face 1b, and a terminal box 8, in order from the light-receiving face 1a side. Moreover, the device group 6 includes a plurality of solar cell devices 9, and an inner lead 10 which connects the adjacent solar cell devices 9 to each other. Further, the configuration made of the light-transmitting substrate 2, the covering member 3, the connection wiring 4, the bypass device 5, the device group 6, and the protective sheet 7 may be referred to as a solar cell panel 1A. In the following description, a direction toward the light-receiving face 1a from the rear face 1b is referred to as a light-receiving face direction, and a direction toward the rear face 1b from the light-receiving face 1a is referred to as a rear face direction.

The light-transmitting substrate 2 has a function of working as a substrate of the solar cell module 1. For example, tempered glass, super white glass or the like is used as the light-transmitting substrate 2.

The covering member 3 has the function of covering and protecting the connection wiring 4, the bypass device 5, and the device group 6. Further, the covering member 3 seals the connection wiring 4, the bypass device 5, and the device group 6, between the light-transmitting substrate 2 and the protective sheet 7. As a covering member 3, ethylene vinyl acetylated copolymer, or heat curable resin such as polyethylene, polyvinyl butyral and the like, of which a thickness is 0.3 mm or more and 0.8 mm or less, is used. In the following description, the covering member 3 which is positioned closer to the light-receiving face 1a side than the device group 6 is assumed to be a first covering member 3a, and the covering member 3 which is positioned closer to the rear face 1b side than the device group 6 is assumed to be a second covering member 3b. The covering member 3 is configured of a pair of members of the first covering member 3a and the second covering member 3b.

The connection wiring 4 electrically connects the adjacent device groups 6. As the connection wiring 4, for example, copper foil where solder is covered, or the like is used.

In the solar cell device 9, due to dust or the like which is piled up on the light-receiving face side, a power generation amount is lowered, and electrical resistance may increase. The bypass device 5 has the function of bypassing a current flowing through the device group 6 which includes the solar cell device 9 where the resistance has increased, into other device groups 6.

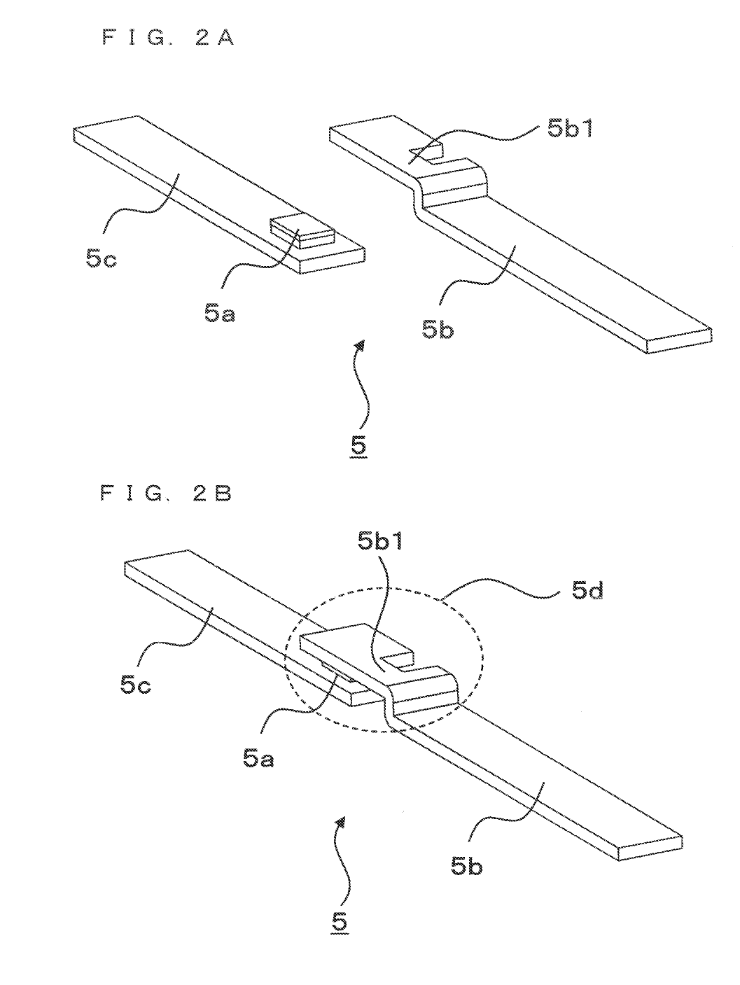

As shown in FIGS. 2A and 2B, the bypass device 5 is configured such that a diode 5a is held between a first conductive plate 5b and a second conductive plate 5c. The diode 5a are bonded to the first conductive plate 5b and the second conductive plate 5c by the solder. The first conductive plate 5b is connected to an cathode electrode of the diode 5a. The second conductive plate 5c is connected to an anode electrode of the diode 5a. The bypass device 5 is placed such that the first conductive plate 5b is positioned on the rear face 1b side, and the second conductive plate 5c is positioned the light-receiving face 1a side.

As a diode 5a, for example, PN diode, Schottky barrier diode or the like can be used. In the Schottky barrier diode, generated heat is smaller than in the PN diode at the time of the current flow. Therefore, if the Schottky barrier diode is used, the covering member 3, the protective sheet 7, or the like is unlikely to be deteriorated by the heat of the diode 5a.

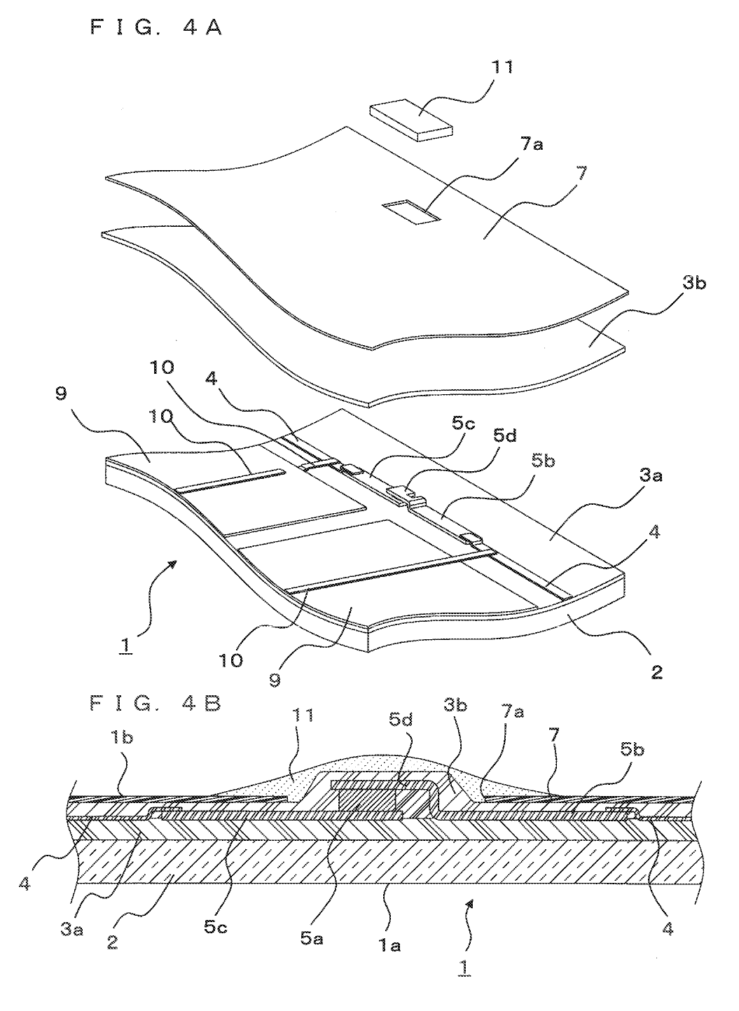

The first conductive plate 5b and the second conductive plate 5c are members which electrically connect the device group 6 and the diode 5a. Specifically, the first conductive plate 5b and the second conductive plate 5c are connected to the device group 6 by the connection wiring 4, as shown in FIGS. 4A and 4B. The first conductive plate 5b and the second conductive plate 5c are connected to the connection wiring 4 by the solder. At this time, the solder which is interposed between the connection portions may form a fillet portion which is radially widened toward the first conductive plate 5b side and the second conductive plate 5c side from the connection wiring 4 side. If the fillet portion is arranged, a connection angle between the solder and the first conductive plate 5b and second conductive plate 5c becomes small. Accordingly, adhesive strength between the connection wiring 4 and the first conductive plate 5b and second conductive plate 5c is enhanced.

For example, a metal plate having a conductivity can be used as the first conductive plate 5b and the second conductive plate 5c. As a material of the metal plate, for example, copper, phosphor bronze, brass, iron, stainless steel or the like is used. For example, shapes of the first conductive plate 5b and the second conductive plate 5c may be a rectangular-shaped flat plate. The thicknesses of the first conductive plate 5b and the second conductive plate 5c may be thicker than that of the connection wiring 4. Accordingly, the first conductive plate 5b and the second conductive plate 5c are likely to absorb the heat which is generated when the current flows through the diode 5a. As a result, heat radiation properties of the bypass device 5 is improved.

The first conductive plate 5b may be made of a plate material bent into almost a crank shape as shown in FIG. 4B. The first conductive plate 5b can be connected to the bypass device 5 using the bent portion. Therefore, the first conductive plate 5b and the second conductive plate 5c are positioned on the same face of the first covering member 3a. As a result, operation of connecting the bypass device 5 and the device group 6 is facilitated. As shown in FIG. 4B, in the vicinity of the diode 5a of the bypass device 5, the convex portion 5d is formed.

As shown in FIGS. 2A and 2B, in the first conductive plate 5b, in the vicinity of the connection portion to the diode 5a, a narrow portion 5b1 of which a width is smaller than other portions, may be arranged. With such a configuration, heat stress which is generated at the time of the heat generation of the diode 5a, is relieved. As a result, peel-off of a soldered portion of the bypass device 5, or the peel-off of the soldered portion of the bypass device 5 and the device group 6 can be reduced.

Furthermore, when the Schottky barrier diode is used as the diode 5a, as size of the bypass device 5, for example, the diode 5a may be 4 mm in vertical dimension, 4 mm in horizontal dimension, and 1 mm in height, the first conductive plate 5b and the second conductive plate 5c may be 40 mm in length and 0.5 mm in thickness, and the thickness of the convex portion 5d may be approximately 2 mm.

The inner lead 10 electrically connects adjacent solar cell devices 9 to each other. As an inner lead 10, for example, the copper foil or the like where the solder for connecting the solar cell device 9 is covered, is used.

The solar cell device 9 converts incident light into electricity. For example, such solar cell device 9 includes a substrate which is configured of monocrystalline silicon, polycrystalline silicon or the like, and electrodes which are arranged on a surface (upper face) and a rear face (lower face) of the substrate. The solar cell device 9 including the monocrystalline silicon substrate or the polycrystalline silicon substrate, forms, for example, a square shape. At this time, for example, it is sufficient that the size of one side of the solar cell device 9 is 100 mm or more and 200 mm or less.

Furthermore, a type of the solar cell device 9 is not limited in particular. For example, a thin film-based solar cell device which is formed of the material such as amorphous silicon, CIGS or CdTe, may be used. The thin film-based solar cell device described above can be used, for example, by appropriately stacking a photoelectric conversion layer such as an amorphous silicon layer, a CIGS layer, or a CdTe layer, and a transparent electrode, on a glass substrate. The photoelectric conversion layer and the transparent electrode on the glass substrate are integrated by carrying out patterning thereon, and thereby, the thin film-based solar cell device is obtained. Therefore, in the thin film-based solar cell device, the inner lead 10 is not used. Still more, the thin film-based solar cell device forms a belt shape. Furthermore, the solar cell device 9 may be a type that a thin film of amorphous silicon is formed on the monocrystalline silicon substrate or the polycrystalline silicon substrate.

The protective sheet 7 has the function of protecting the rear face 1b of the solar cell module 1. The protective sheet 7 is bonded to the covering member 3 which is positioned on the rear face 1b side of the solar cell module 1. In other words, the protective sheet 7 is placed so as to hold the covering member 3, with each of the device groups 6 (for example, a first device group 6a and a second device group 6b). For the protective sheet 7, for example, polyvinyl fluoride (PVF) of which the thickness is 0.3 mm or more and 0.5 mm or less, polyethylene terephthalate (PET), polyethylene naphthalate (PEN), or the resin of stacking two or more of the above types, can be used. The protective sheet 7 maintains a sheet shape even in the case of being heated, and has the properties of which expansion and contraction, and deformation are unlikely to be generated as compared to the covering member 3. Further, heat conductivity of the PVF is 0.14 W/m·K or higher and 0.17 W/m·K or lower. The head conductivity of the PET is 0.20 W/m·K or higher and 0.33 W/m·K or lower. The heat conductivity of the PEN is approximately 0.1 W/m·K. In addition, the protective sheet 7 includes an opening portion 7a. The opening portion 7a has almost the same size as the size of the convex portion 5d of the bypass device 5 when seen in plan view from the rear face 1b side. Accordingly, it is sufficient that the width of the opening portion 7a is almost equal to the width of the first conductive plate 5b.

The terminal box 8 is provided to lead out output which is obtained by the solar cell device 9 to the outside. The terminal box 8 includes a box, a terminal plate which is placed within the box, and an output cable which leads electric power to the outside of the box. As a material of the box, for example, denatured polyphenylene ether resin, or polyphenylene oxide resin is used.

Next, a detailed structure of the solar cell module 1 will be described.

### First Embodiment

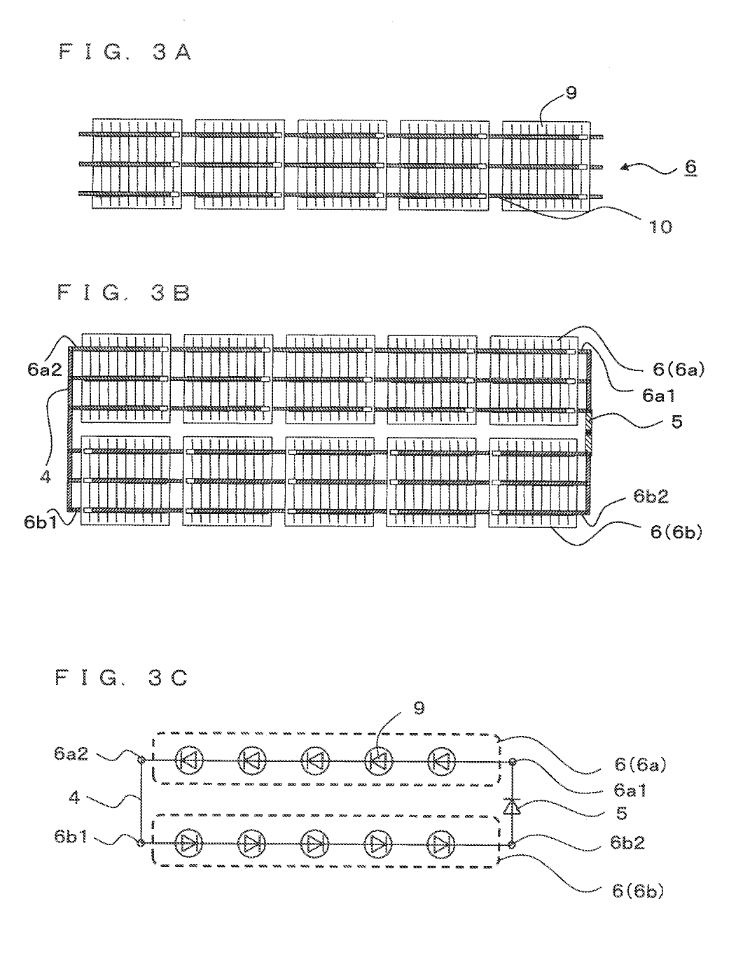

In the device group 6 shown in FIG. 3A, among the solar cell devices 9 which are arrayed in a linear shape, three electrodes which are positioned on the surface of one side of the adjacent solar cell devices 9 are electrically connected to three electrodes which are positioned on the rear face of the other side of the solar cell devices 9, by the inner lead 10. As a result, the plurality of solar cell devices 9 are connected in series, and thereby, the device group 6 is configured. Furthermore, one end of the device group 6 becomes a positive electrode side output end which has a positive potential, and the other end becomes a negative electrode side output end which has a negative potential.

The solar cell module 1 includes a plurality of device groups 6. Specifically, as shown in FIG. 1A, the solar cell module 1 includes the first device group 6a, the second device group 6b, a third device group 6c, a fourth device group 6d, a fifth device group 6e, and a sixth device group 6f. The first device group 6a includes a first positive electrode side output end 6a1 and a first negative electrode side output end 6a2. The second device group 6 includes a second positive electrode side output end 6b1 and a second negative electrode side output end 6b2.

Next, a connection form between the first device group 6a and the second device group 6b will be described. As shown in FIG. 3B and FIG. 3C, in the first device group 6a and the second device group 6b, the first positive electrode side output end 6a1 and the second negative electrode side output end 6b2 are positioned on the same side. Therefore, the first positive electrode side output end 6a1 and the second negative electrode side output end 6b2 are placed on almost the same axis. Moreover, in the first device group 6a and the second device group 6b, the first negative electrode side output end 6a2 and the second positive electrode side output end 6b1 are positioned on the same side. Therefore, the first negative electrode side output end 6a2 and the second positive electrode side output end 6b1 are placed on almost the same axis. Thus, the first negative electrode side output end 6a2 and the second positive electrode side output end 6b1 are electrically connected in series by the connection wiring 4. Still more, the first positive electrode side output end 6a1 and the second negative electrode side output end 6b2 are electrically connected through the bypass device 5. Here, the bypass device 5 is connected to the first device group 6a and the second device group 6b, in parallel.

In the present embodiment, as shown in FIG. 3B, in order to collect the first positive electrode side output ends 6a1 into one, three inner leads 10 of the first positive electrode side output end 6a1 are connected by the connection wiring 4. Furthermore, in the present embodiment, in order to collect the second negative electrode side output ends 6b2 into one, three inner leads 10 of the second negative electrode side output end 6b2 are connected by the connection wiring 4. As shown in FIG. 1A, in other solar cell device groups, the connection wiring 4 and the bypass device 5 are arranged in the same manner. Further, the second device group 6b and the third device group 6c are connected by the connection wiring 4, and the fourth device group 6d and the fifth device group 6e are also connected by the connection wiring 4.

In this manner, in the present embodiment, since the bypass device 5 is arranged at a desired position, damage due to a temperature increase of the solar cell device 9 is reduced, even when a shadow is generated on the light-receiving face of an arbitrary device group 6 (solar cell device 9).

In the present embodiment, as shown in FIGS. 4A and 4B, the opening portion 7a of the protective sheet 7 is located at a position facing the convex portion 5d of the bypass device 5. That is, the protective sheet 7 includes the opening portion 7a in the portion overlapping with the bypass device 5, in plan view. The opening portion 7a is a hole portion penetrating the protective sheet 7 in a thickness direction. Accordingly, the convex portion 5d of the bypass device 5 is exposed from the opening portion 7a of the protective sheet 7. Therefore, when the height of the convex portion 5d is greater than the thickness of the protective sheet 7, the convex portion 5d protrudes from the opening portion 7a. Further, the convex portion 5d of the bypass device 5 is covered by the second covering member 3b. Thus, the bypass device 5 is protected. At this time, the second covering member 3b is also exposed from the opening portion 7a.

In this manner, in the present embodiment, since the protective sheet 7 is placed on the covering member 3 so that the bypass device 5 is positioned at a region of the opening portion 7a, the generation of wrinkles of the protective sheet 7 due to the convex portion 5d of the bypass device 5, is reduced. Accordingly, since decrease in strength of the protective sheet 7 is suppressed, reliability of the solar cell module 1 is improved. Moreover, if the covering member 3 is configured of the material described above, since the covering member 3 is likely to be expand by the heating before cross-linking, the bypass device 5 is likely to be sealed. As a result, humidity resistance of the bypass device 5 is enhanced.

Moreover, a portion (for example, the convex portion 5d) of the bypass device 5 and a portion of the second covering member 3b covering the convex portion 5d may protrude from the opening portion 7a to the outside, as shown in FIG. 4B. As a result, a contact area with the outside air of the portion which protrudes from the opening portion 7a to the outside becomes large. Therefore, the bypass device 5 is likely to be cooled by the outside air through the covering member 3, even when the heat is generated in the bypass device 5.

Furthermore, in the present embodiment, as shown in FIG. 4B, the opening portion 7a, the convex portion 5d of the bypass device 5 protruding from the opening portion 7a, and the second covering member 3b may be covered by an auxiliary member 11. The auxiliary member 11 protects the second covering member 3b and the bypass device 5. For the auxiliary member 11, for example, material such as silicone sealant, silicone rubber, ethylene propylene rubber (EPDM), or fluororubber which is good in heat resistance, humidity resistance, and insulating properties can be used. If such material is used, a change in physical properties and the shape of the auxiliary member 11 is unlikely to occur, even when the solar cell module 1 is used for relatively a long period. Further, if the material which becomes an elastic body after curing is used for the auxiliary member 11, the adhesive strength is unlikely to be lowered by melting of the auxiliary member 11, even when the diode 5a is at a high temperature.

Moreover, for the auxiliary member 11, for example, material in which metal particles or ceramic particles of the high heat conductivity is contained in the material such as the rubber described above may be used. In this case, the heat conductivity of the auxiliary member 11 is enhanced. As a result, the heat radiation properties of the auxiliary member 11 are improved. As a metal particle, for example, aluminum (heat conductivity: 236 W/m·K), copper (heat conductivity: 398 W/m·K), or silver (heat conductivity: 420 W/m·K) is used. Further, as a ceramic particle, for example, alumina (heat conductivity: 32 W/m·K), zirconia (heat conductivity: 3 W/m·K), or the like is used. In addition, in the ceramic particles, the insulating properties of the auxiliary member 11 can be secured. For example, it is sufficient that the sizes of the metal particle and the ceramic particle are 0.1 mm or more and 1.2 mm or less in diameter. It is sufficient that a content of the metal particles or the ceramic particles to a main material such as the rubber described above is 5% or more and 40% or less by mass ratio conversion with respect to the main material. With such a configuration, the heat conductivity of the auxiliary member 11 is improved, and formability and adhesive properties of the main material can be maintained.

The auxiliary member 11 may have a sheet shape that is obtained by processing in advance the auxiliary member 11. Specifically, for example, a heat conductive filler is mixed into a binder of the rubber or synthetic resin having elasticity after the curing, and the mixed binder is processed into the sheet shape. At this time, as a binder, for example, silicone rubber, acryl rubber, polyethylene rubber or the like can be used. As a heat conductive filler, graphite, mica, alumina or the like can be used.

### Second Embodiment

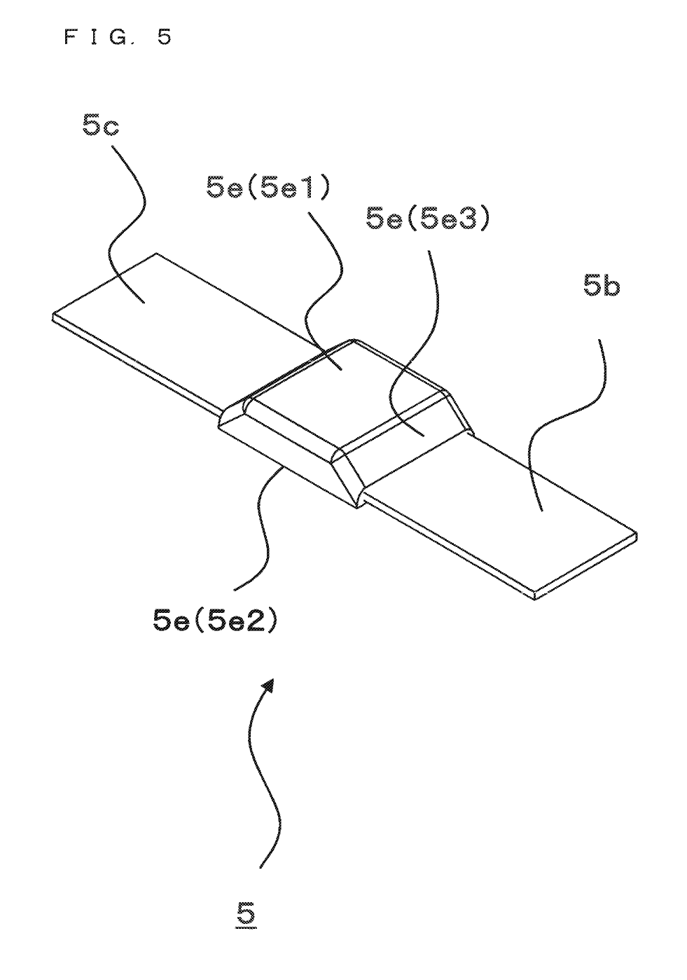

As shown in FIG. 5, a point that the solar cell module 1 according to a second embodiment uses the bypass device 5 including a sealing member 5e which seals the diode 5a, is different from the first embodiment. The sealing member 5e also seals the vicinity of the connection portion of the first conductive plate 5b and the second conductive plate 5c to the diode 5a. As a material of the sealing member 5e, for example, epoxy resin can be used. Hereby, the generation of the peel-off of the diode 5a from the first conductive plate 5b and the second conductive plate 5c is reduced in the connection portion. The sealing member 5e includes an upper face 5e1 that is positioned on the protective sheet 7 side, a lower face 5e2 corresponding to the rear face of the upper face 5e1, and a side face 5e3 that connects the upper face 5e1 and the lower face 5e2 and includes an inclination portion which is inclined toward the upper face 5e1 from the lower face 5e2. Hereby, corners of the protruding portion of the sealing member 5e protruding from the protective sheet 7 can be smoothened. As a result, even when a builder hits the corners of the protruding portion with a tool or the like, the damage to the protective sheet 7 can be reduced. Furthermore, in the present embodiment, it is possible to enhance design properties of the solar cell module 1 when seen from the rear face 1b side.

### Third Embodiment

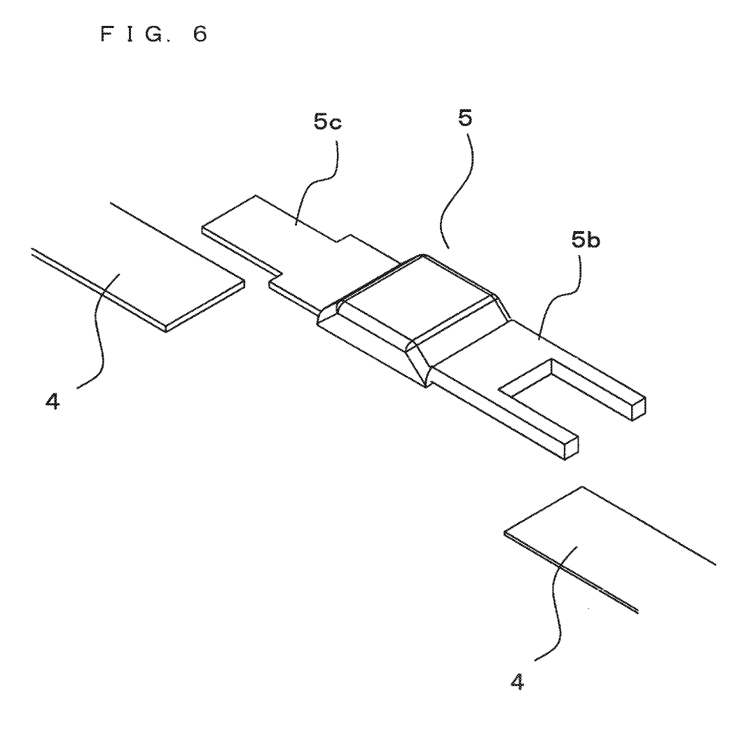

As shown in FIG. 6, the point that the solar cell module 1 according to a third embodiment includes the bypass device 5 where the thickness of the first conductive plate 5b which is connected to a cathode electrode of the diode 5a, is greater than the thickness of the second conductive plate 5c which is connected to an anode electrode of the diode 5a, is different from the embodiments described before. The heat generation amount of the diode 5a at the time of bypassing the current into a desired device group 6 by the bypass device 5 is greater in the cathode electrode than in the anode electrode. Therefore, in the present embodiment, by allowing the thickness of the first conductive plate 5b which is connected to the cathode electrode to be large, the heat radiation properties of the first conductive plate 5b is enhanced. Hereby, heat which is generated in the diode 5a can be efficiently radiated.

As shown in FIG. 6, if the shape of the first conductive plate 5b and the shape of the second conductive plate 5c are different from each other in the bypass device 5, an error in attaching the first conductive plate 5b to the diode 5a is unlikely to be generated. In the case of the bypass device 5 shown in FIG. 6, the length of an outer periphery of the first conductive plate 5b and the second conductive plate 5c is greater than the length of the outer periphery of the first conductive plate 5b and the second conductive plate 5c of the bypass device 5 shown in FIG. 5. Hereby, since the length of the fillet portion which may be generated at the time when the first conductive plate 5b and the second conductive plate 5c are bonded to the connection wiring 4 by the solder, becomes large, the adhesive strength is enhanced.

### Fourth Embodiment

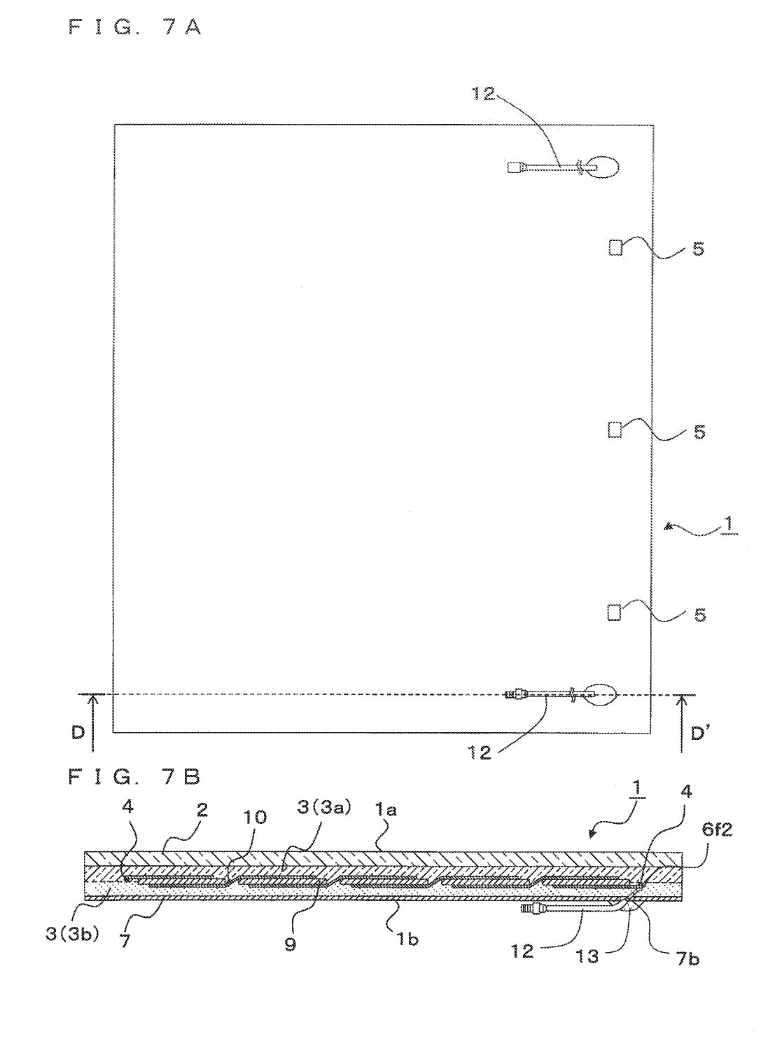

As shown in FIGS. 7A and 7B, the point that the solar cell module 1 according to a fourth embodiment does not include the terminal box 8, is different from the embodiments described before.

In the present embodiment, among two output cables 12, one output cable 12 is electrically connected to the first positive electrode side output end 6a1 through a hole portion 7b which is arranged in the protective sheet 7. The other output cable 12 is electrically connected to a sixth negative electrode side output end 6f2 through the hole portion 7b which is arranged in the protective sheet 7. The output cables 12 are fixed to the rear face 1b by a potting 13 such as epoxy resin which fills the vicinity of the hole portion 7b.

In the present embodiment, by removing the terminal box 8, the number of the members is reduced, and productivity can be enhanced.

### Fifth Embodiment

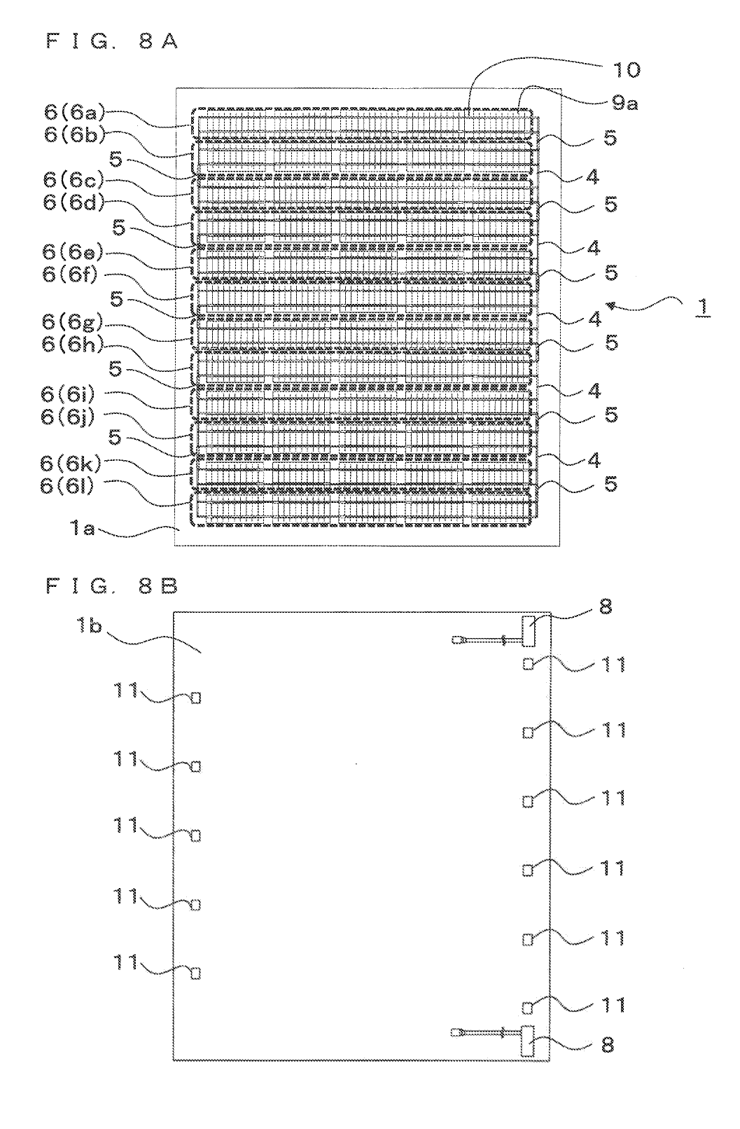

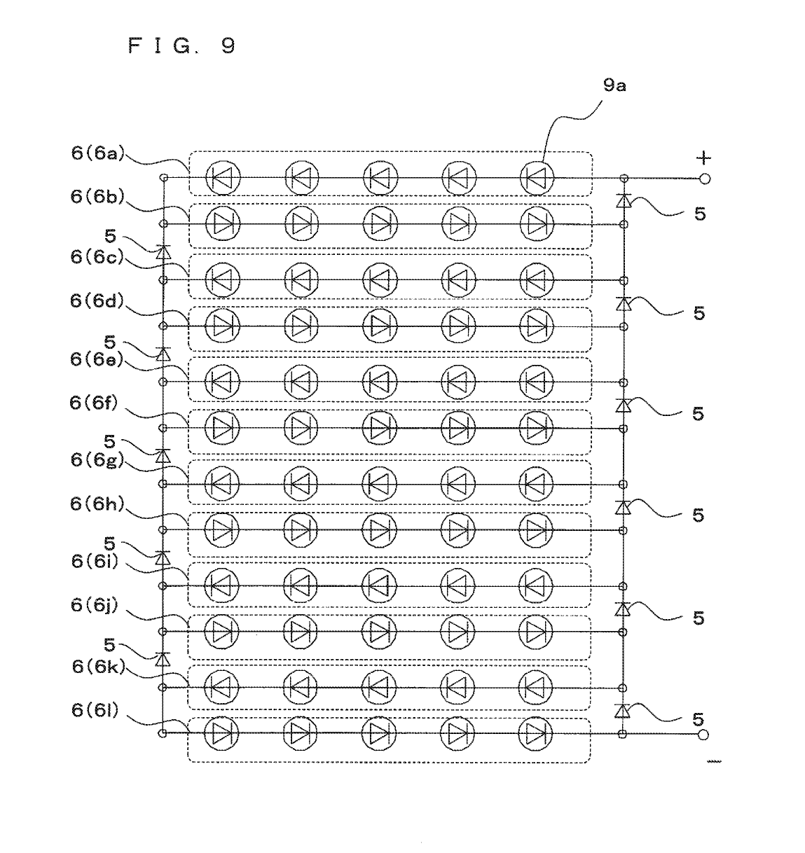

As shown in FIG. 8A, FIG. 8B and FIG. 9, the point that the solar cell module 1 according to a fifth embodiment uses the solar cell device 9a having half the size of the solar cell device 9 shown in FIG. 1A or the like, is different from the embodiments described before. In the present embodiment, the point that the bypass device 5 is attached alternately to one end side and the other end side of the device group 6, is different from the embodiments described before.

The shape of the solar cell device 9a according to the present embodiment, is a rectangular shape which is obtained by dividing the solar cell device 9 according to the embodiments described before at almost the center along the longitudinal direction of the inner lead 10. Such solar cell device 9a can be formed by processing the solar cell device 9 by laser or the like. In the present embodiment, a state in which two inner leads 10 are placed in a solar cell device 9a is shown, but the number of the inner leads 10 is not limited to two, and one or three or more of the inner leads 10 may be placed.

In the present embodiment, by using the solar cell device 9a, a structure where twelve device groups 6 are connected in series is formed. On the other hand, a light-receiving area of the solar cell module 1 of the present embodiment has a light-receiving area which is equal to the embodiments described before. Hereby, in the present embodiment, when the solar cell module of the same size as the embodiments described before is used, a voltage of the solar cell module becomes approximately twice the embodiments described before, and the current becomes approximately half. In this manner, the electrical power is the same, the voltage is enhanced, and the current is reduced, and thereby, a loss in the connection wiring 4 or the like can be reduced.

Furthermore, on one end side (right side in FIG. 8A), the solar cell module 1 includes the bypass devices 5 between the first device group 6a and the second device group 6b, between the third device group 6c and the fourth device group 6d, between the fifth device group 6e and the sixth device group 6f, between a seventh device group 6g and an eighth device group 6h, between a ninth device group 6i and a tenth device group 6j, and between an eleventh device group 6k and a twelfth device group 6l. Further, on the other side (left side in FIG. 8A), the solar cell module 1 includes the bypass devices 5 between the second device group 6b and the third device group 6c, between the fourth device group 6d and the fifth device group 6e, between the sixth device group 6f and the seventh device group 6g, between the eighth device group 6h and the ninth device group 6i, and the tenth device group 6j and the eleventh device group 6k.

In this manner, in the present embodiment, by alternately placing the bypass device 5 on one end side and the other end side of the solar cell module 1, the current is likely to be bypassed into other device groups even when a hot spot is generated in the certain device group 6. Hereby, the heat generation of the solar cell module 1 can be reduced.

### Sixth Embodiment

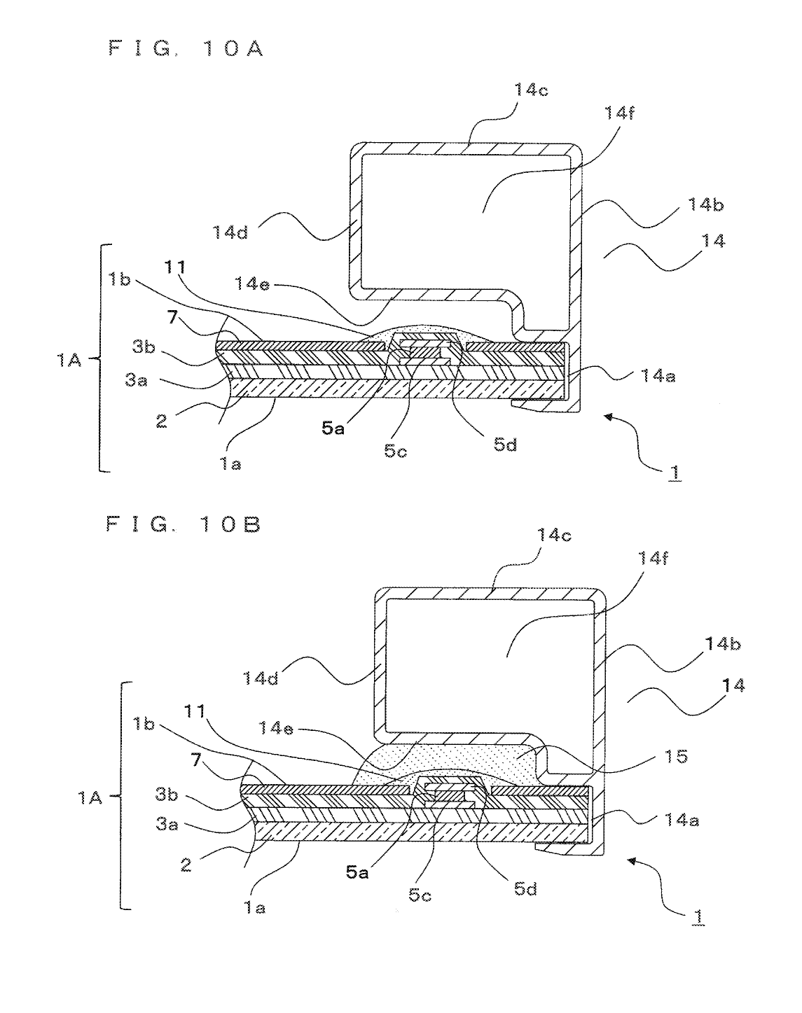

As shown in FIGS. 10A and 10B, the point that the solar cell module 1 according to a sixth embodiment includes a frame member 14 which protects the outer periphery of the solar cell module 1 and cover the bypass device 5 is different from the embodiments described before.

As shown in FIG. 10A, the frame member 14 includes an engaging portion 14a which holds a portion of the light-receiving face 1a and a portion of the rear face 1b in an outer peripheral portion of a solar cell panel 1A. Furthermore, the frame member 14 includes an outer wall face 14b that extends toward an opposite direction to the light-transmitting substrate 2 from the engaging portion 14a, a bottom face 14c that protrudes toward the center of the solar cell module 1 from the end portion of the outer wall face 14b, an inner wall face 14d that is placed in almost parallel with the outer wall face 14b from the end portion of the center side of the solar cell module 1 of the bottom face 14c, and an extending portion 14e that connects the inner wall face 14d and the outer wall face 14b at the position which is close to the protective sheet 7 more than the bottom face 14c. Further, the frame member 14 forms a hollow portion 14f which is surrounded by the outer wall face 14b, the bottom face 14c, the inner wall face 14d, and the extending portion 14e.

Therefore, in the present embodiment, the extending portion 14e is placed so as to project to the position facing the bypass device 5. In other words, the extending portion 14e is placed in the portion overlapping with the bypass device 5 in plan view. Thus, in the present embodiment, the bypass device 5 can be protected by the extending portion 14e from the rear face side of the solar cell module 1. Hereby, when the tools which are used by an operator or other members, come into contact with the bypass device 5 at the time of arranging the solar cell module 1, the damage to the bypass device 5 due to the contact is reduced. As a result, the reliability of the solar cell module 1 is improved.

For example, such frame member 14 can be formed by extrusion molding of aluminum alloy, or the like.

Furthermore, in the present embodiment, when a gap is generated between the bypass device 5 and the extending portion 14e, the gap may be filled with a filling material 15. Hereby, when the extending portion 14e comes into contact with the bypass device 5 due to wind or snow fall, the damage due to the contact can be reduced.

The filling material 15 may have the heat conductivity which is higher than the protective sheet 7. Hereby, since the heat which is generated in the bypass device 5 is transmitted to the frame member 14, the heat radiation properties of the solar cell module 1 is enhanced. As a filling material 15, for example, the resin of the silicone rubber (heat conductivity: 1.3 W/m·K) having the high heat conductivity, or the like can be used. Furthermore, in the filling material 15, metal particles and/or ceramic particles of which the heat conductivity is higher than the resin, may be contained in the resin such as the silicone sealant and/or the silicone rubber, in the same manner as the auxiliary member 11. Hereby, the heat radiation properties are enhanced more. Further, the particles which are contained in the resin, may be adjusted using the same material and mixture as the auxiliary member 11.

Furthermore, the present invention is not limited the embodiments described above, and can be applied to an optional embodiment as long as being departed from the scope of the present invention.

### REFERENCE SIGNS LIST

1 SOLAR CELL MODULE
1A SOLAR CELL PANEL
1a LIGHT-RECEIVING FACE
1b REAR FACE
2 LIGHT-TRANSMITTING SUBSTRATE
3 COVERING MEMBER
3a FIRST COVERING MEMBER
3b SECOND COVERING MEMBER
4 CONNECTION WIRING
5 BYPASS DEVICE
5a DIODE
5b FIRST CONDUCTIVE PLATE
5b1 NARROW PORTION
5c SECOND CONDUCTIVE PLATE
5d CONVEX PORTION
5e SEALING MEMBER
5e1 UPPER FACE
5e2 LOWER FACE
5e3 SIDE FACE
6 SOLAR CELL DEVICE GROUP (DEVICE GROUP)
6a to 6l FIRST DEVICE GROUP TO TWELFTH DEVICE GROUP
6a1 FIRST POSITIVE ELECTRODE SIDE OUTPUT END
6a2 FIRST NEGATIVE ELECTRODE SIDE OUTPUT END
6b1 SECOND POSITIVE ELECTRODE SIDE OUTPUT END
6b2 SECOND NEGATIVE ELECTRODE SIDE OUTPUT END
6f2 SIXTH NEGATIVE ELECTRODE SIDE OUTPUT END
7 PROTECTIVE SHEET
7a OPENING PORTION
7b HOLE PORTION
8 TERMINAL BOX
9, 9a SOLAR CELL DEVICE
10 INNER LEAD
11 AUXILIARY MEMBER
12 OUTPUT CABLE
13 POTTING
14 FRAME MEMBER
14a ENGAGING PORTION
14b OUTER WALL FACE
14c BOTTOM FACE
14d INNER WALL FACE
14e EXTENDING PORTION
14f HOLLOW PORTION
15 FILLING MATERIAL

1. A solar cell module comprising:
a first solar cell device group including a plurality of solar cell devices electrically connected to each other;
a second solar cell device group including a plurality of solar cell devices electrically connected to each other;
a bypass device that is electrically connected to the first solar cell device group and the second solar cell device group;
a covering member that covers the first solar cell device group, the second solar cell device group, and the bypass device; and
a protective sheet that is located on the covering member,
the protective sheet including an opening portion that is located at a position facing the bypass device.

2. The solar cell module according to claim 1, further comprising:
an auxiliary member on the protective sheet, the auxiliary member covering the opening portion.

3. The solar cell module according to claim 1,
wherein a portion of the bypass device and a portion of the covering member protrude from the opening portion.

4. The solar cell module according to claim 1,
wherein the bypass device includes:
a diode; and
a sealing member that seals the diode, and
the sealing member includes:
an upper face that is located on the protective sheet side;
a lower face that is located on an opposite side to the upper face; and
a side face that connects the upper face and the lower face, the side face including an inclination portion which is inclined toward the upper face from the lower face.

5. The solar cell module according to claim 1,
wherein the bypass device includes:
a diode;
a first conductive plate that is connected to a cathode electrode of the diode; and
a second conductive plate that is connected to an anode electrode of the diode, and
a thickness of the first conductive plate is greater than a thickness of the second conductive plate.

6. The solar cell module according to claim 1, further comprising:
a solar cell panel including the first solar cell device group, the second solar cell device group, the bypass device, and the protective sheet, and
a frame member including:
an engaging portion which engages with an outer peripheral portion of a solar cell panel; and
an extending portion which is connected to the engaging portion, the extending portion facing the bypass device.

7. The solar cell module according to claim 6, further comprising:
a filling material between the extending portion and the bypass device, the heat conductivity of the filling material being higher than that of the protective sheet.

8. The solar cell module according to claim 7,
wherein the filling material includes:
resin; and
a particle, the heat conductivity of the particle being higher than that of the resin.

9. The solar cell module according to claim 1,
wherein the bypass device includes a diode.

10. The solar cell module according to claim 1,
wherein a portion of the bypass device and a portion of the covering member are in the opening portion.

11. The solar cell module according to claim 2,
wherein the auxiliary member further covers the covering member at the opening portion.

12. The solar cell module according to claim 2,
wherein the covering member includes a protruding portion protruding from the opening portion, and
the auxiliary member further covers the protruding portion.

13. The solar cell module according to claim 2,
wherein the protective sheet further includes:
a first surface on the covering member; and
a second surface on the opposite side to the first surface, and
the auxiliary member is on the second surface.

14. The solar cell module according to claim 2,
wherein the auxiliary member includes a metal particle or a ceramic particle.

15. A solar cell module comprising:
a first solar cell device group including a plurality of solar cell devices electrically connected to each other;
a second solar cell device group including a plurality of solar cell devices electrically connected to each other;
a bypass device that is electrically connected to the first solar cell device group and the second solar cell device group, the bypass device uncovered by a protective sheet;
a covering member that covers the first solar cell device group, the second solar cell device group, and the bypass device; and
the protective sheet that is located on the covering member.
